(19) United States
(12) Patent Application Publication
(10) Pub. No.: US 2025/0081429 A1
(43) Pub. Date: Mar. 6, 2025

(54) SEMICONDUCTOR DEVICE

(71) Applicant: Samsung Electronics Co., Ltd., Suwon-si (KR)

(72) Inventors: Youmin Ban, Suwon-si (KR); Daeyoung Moon, Suwon-si (KR); Changwoo Seo, Suwon-si (KR); Suyoun Song, Suwon-si (KR); Hyungjun Hwang, Suwon-si (KR)

(21) Appl. No.: 18/664,753

(22) Filed: May 15, 2024

(30) Foreign Application Priority Data
Sep. 1, 2023 (KR) 10-2023-0116266

(51) Int. Cl. H10B 12/00

(52) U.S. Cl. CPC H10B 12/315; H10B 12/0335; H10B 12/36; H10B 12/482; H10B 12/488

(57) ABSTRACT

A semiconductor device includes a substrate, an active region defined by a device isolation layer within the substrate, a word line extending in a first horizontal direction within the substrate, a bit line extending on the substrate in a second horizontal direction intersecting with the first horizontal direction and including a metal-based conductive pattern, a first spacer on a sidewall of the metal-based conductive pattern, a second spacer on the first spacer, a direct contact in a direct contact hole exposing the active region and electrically connecting the bit line to the active region, and a buried spacer on a lower sidewall of the direct contact within the direct contact hole, wherein the second spacer contacts a sidewall of the direct contact on the sidewall of the direct contact.

### CROSS-REFERENCE TO RELATED APPLICATION(S)

This application is based on and claims priority under 35 U.S.C. § 119 to Korean Patent Application No. 10-2023-0116266, filed on Sep. 1, 2023, in the Korean Intellectual Property Office, the disclosure of which is incorporated by reference herein in its entirety.

### BACKGROUND

The inventive concept relates generally to a semiconductor device, and more particularly, to a semiconductor device including peripheral circuit elements.

As the electronics industry develops rapidly and user demands increase, electronic devices are being made smaller and lighter. Accordingly, as semiconductor devices with high integration which are used in electronic devices are required, design rules for the configurations of semiconductor devices are decreasing.

### SUMMARY

The inventive concept, as manifested in one or more embodiments thereof, provides a semiconductor device with improved performance and reliability.

The inventive concept is not limited to the illustrative embodiments described herein, but rather other embodiments not explicitly described may become apparent to those skilled in the art from the description below.

According to an aspect of the inventive concept, there is provided a semiconductor device. The semiconductor device includes a substrate, an active region defined by a device isolation layer within the substrate, a word line extending in a first horizontal direction within the substrate, a bit line extending on the substrate in a second horizontal direction intersecting with the first horizontal direction and including a metal-based conductive pattern, a first spacer on a sidewall of the metal-based conductive pattern, a second spacer on the first spacer, a direct contact in a direct contact hole exposing the active region and electrically connecting the bit line to the active region, and a buried spacer on a lower sidewall of the direct contact within the direct contact hole, wherein the second spacer contacts the sidewall of the direct contact on the sidewall of the direct contact.

According to another aspect of the inventive concept, there is provided a semiconductor device. The semiconductor device includes a substrate, an active region defined by a device isolation layer within the substrate, a word line crossing the active region in a first horizontal direction and dividing the active region into a first impurity region and a second impurity region, a bit line extending in a second horizontal direction intersecting with the first horizontal direction on the substrate and including a conductive semiconductor pattern and a metal-based conductive pattern that are sequentially stacked in a vertical direction perpendicular to the first and second horizontal directions, a first spacer on a sidewall of the metal-based conductive pattern, a second spacer on the first spacer, a direct contact in a direct contact hole exposing the first impurity region and connecting the bit line to the first impurity region, a buried contact in a buried contact hole exposing the second impurity region and electrically connected to the second impurity region on a sidewall of the bit line, and a buried spacer on a lower sidewall of the direct contact within the direct contact hole, wherein the second spacer contacts the sidewall of the conductive semiconductor pattern on the sidewall of the conductive semiconductor pattern.

According to another aspect of the inventive concept, there is provided a semiconductor device. The semiconductor device includes a substrate, a device isolation layer defining an active region within the substrate, the active region including a first impurity region and second impurity regions spaced apart from each other with the first impurity region therebetween, a word line crossing between the first impurity region and the second impurity region and extending in a first horizontal direction within the substrate, a bit line extending in a second horizontal direction intersecting with the first horizontal direction on the substrate and including a conductive semiconductor pattern and a metal-based conductive pattern that are sequentially stacked in a vertical direction perpendicular to the first and second horizontal directions, a first spacer on a sidewall of the metal-based conductive pattern and including nitride, a second spacer on the first spacer and a sidewall of the conductive semiconductor pattern and including oxide, a direct contact in a direct contact hole exposing the first impurity region and connecting the bit line to the first impurity region, a buried contact in a buried contact hole exposing the second impurity region and electrically connected to the second impurity region on a sidewall of the bit line, and a buried spacer on a lower sidewall of the direct contact within the direct contact hole, wherein the second spacer contacts the sidewall of the direct contact on the sidewall of the direct contact, and contacts the sidewall of the conductive semiconductor pattern on the sidewall of the conductive semiconductor pattern.

### BRIEF DESCRIPTION OF THE DRAWINGS

Embodiments of the inventive concept will be more clearly understood from the following detailed description taken in conjunction with the accompanying drawings, wherein like reference numerals (when used) indicate corresponding elements throughout the several views, and in which:

FIG. 1 is a plan view layout diagram showing the main components of an example semiconductor device, according to one or more embodiments;

FIG. 2 is a plan view layout diagram showing some components of an example semiconductor device, according to one or more embodiments;

FIGS. 3A to 3D are cross-sectional views of the semiconductor device shown in FIG. 1 taken along lines A-A′, B-B′, C-C′, and D-D′, respectively;

FIG. 4 is an enlarged cross-sectional view of a region EX1 of the semiconductor device shown in FIG. 3A;

FIG. 5 is a graph for explaining an example method of manufacturing a semiconductor device according to one or more embodiments; and

FIGS. 6 to 14 are schematic diagrams showing intermediate processes in an example method of manufacturing a semiconductor device, according to one or more embodiments.

### DETAILED DESCRIPTION

Hereinafter, embodiments of the inventive concept are described in detail with reference to the attached drawings.

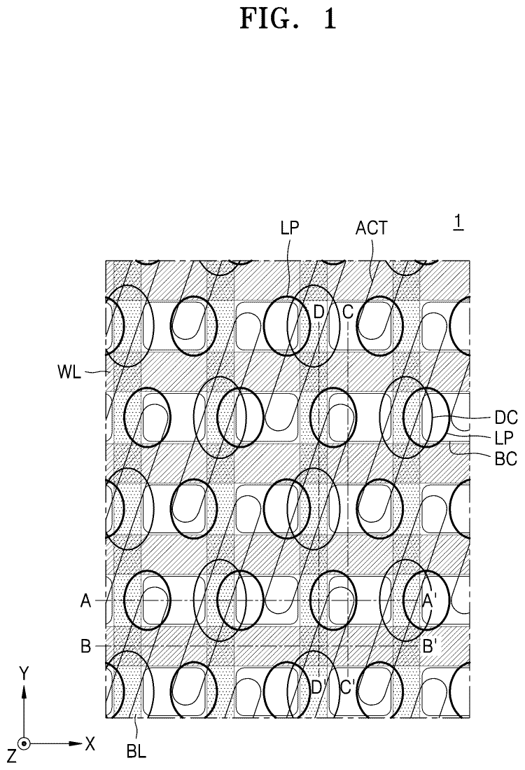

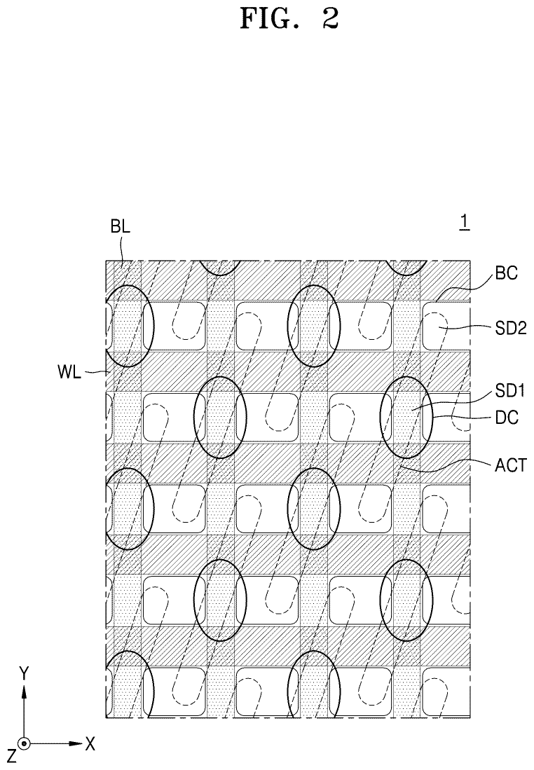

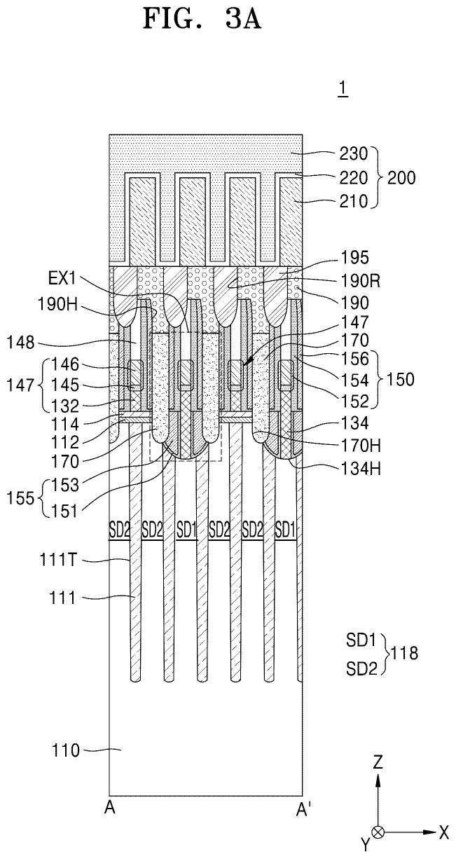

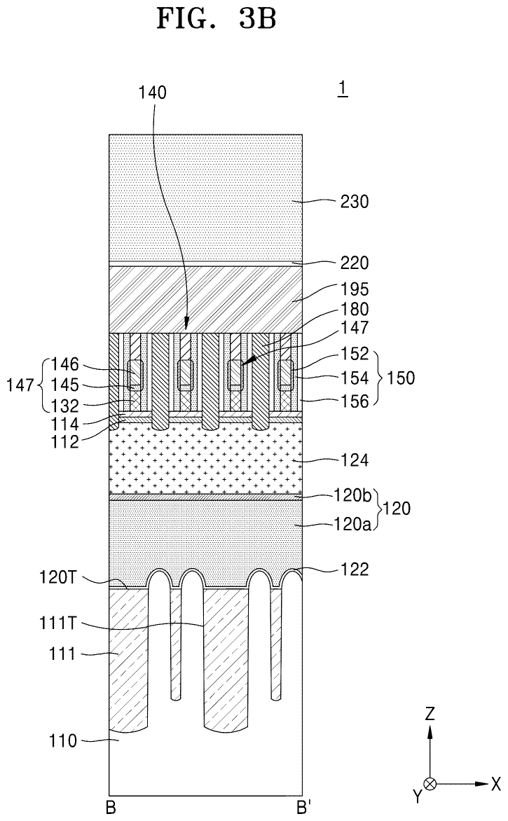

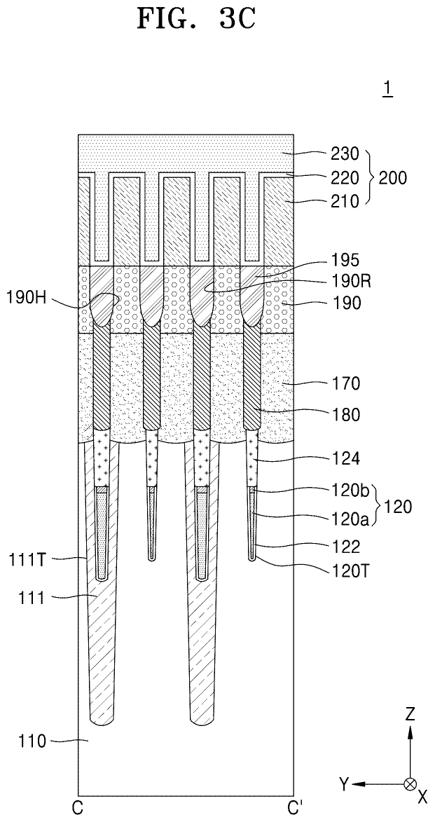

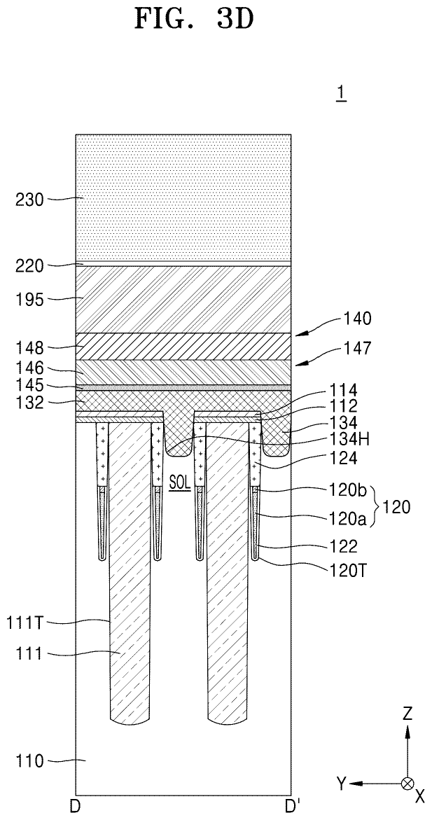

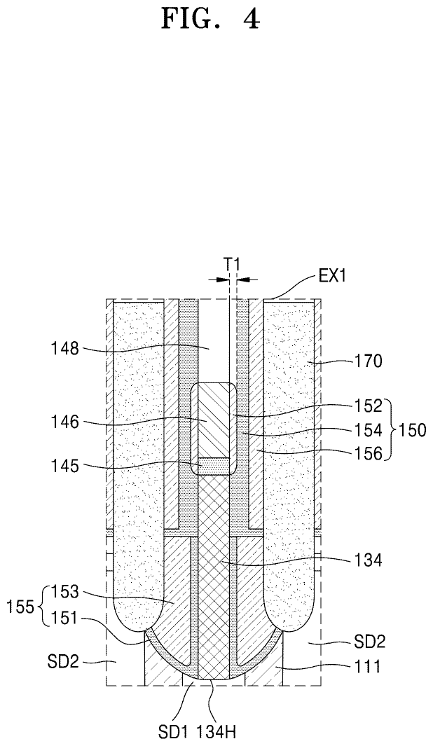

FIG. 1 is a plan view layout diagram showing the main components of an example semiconductor device 1 according to one or more embodiments. FIG. 2 is a plan view layout diagram showing some components of the semiconductor device 1 according to one or more embodiments. FIGS. 3A to 3D are cross-sectional views of the semiconductor device 1 shown in FIG. 1, taken along lines A-A′, B-B′, C-C′, and D-D′, respectively. FIG. 4 is an enlarged cross-sectional view of a region EX1 of the semiconductor device shown in FIG. 3A.

Referring to FIG. 1, the semiconductor device 1 may include a plurality of active regions ACT formed in a memory cell region CR. In some embodiments, the plurality of active regions ACT disposed in the memory cell region CR may be configured having long axes arranged diagonally with respect to a first horizontal direction (X direction) and a second horizontal direction (Y direction). A plurality of active regions ACT may constitute a plurality of active areas 118 illustrated in FIGS. 3A to 3D.

A plurality of word lines WL may extend parallel to each other in the first horizontal direction (X direction) across the plurality of active regions ACT. On the plurality of word lines WL, a plurality of bit lines BL may extend in parallel with each other in the second horizontal direction (Y direction) that intersects with the first horizontal direction (X direction).

In some embodiments, a plurality of buried contacts BC may be formed between two adjacent bit lines BL among the plurality of bit lines BL. In some embodiments, the plurality of buried contacts BC may be arranged in a line in each of the first horizontal direction (X direction) and the second horizontal direction (Y direction).

A plurality of landing pads LP may be formed on the plurality of buried contacts BC. The plurality of landing pads LP may be arranged to at least partially overlap the plurality of buried contacts BC. The term “overlap” (or “overlapping,” or like terms), as may be used herein, is intended to broadly refer to a first element that intersects with at least a portion of a second element in the vertical direction (i.e., Z direction) perpendicular to the first and second horizontal directions, but does not require that the first and second elements be completely aligned with one another in a horizontal plane (i.e., in the first horizontal direction X and/or the second horizontal direction Y). In some embodiments, each of the plurality of landing pads LP may extend to the upper portion of one of the two adjacent bit lines BL.

A plurality of storage nodes (not explicitly shown) may be formed on the plurality of landing pads LP. The plurality of storage nodes may be formed on upper portions of the plurality of bit lines BL. Each of the plurality of storage nodes may be a lower electrode of a plurality of capacitors. The storage node may be connected to the active region ACT through a landing pad LP and a buried contact BC. The term “connected” (or “connecting,” “contact,” “contacting,” or like terms), as may be used herein, is intended to refer to a physical and/or electrical connection between two or more elements, and may include other intervening elements. As used herein, the term “and/or” includes any and all combinations of one or more of the associated listed items.

In detail, referring to FIG. 2 together, the plurality of word lines WL may extend across the plurality of active regions ACT in the first horizontal direction (X direction). The active region ACT may include first impurity regions SD1 and second impurity regions SD2 spaced apart from each other with the first impurity region SD1 therebetween. The word line WL may separate the active region ACT into the first impurity region SD1 and the second impurity region SD2. The first impurity region SD1 and the second impurity region SD2 may be spaced apart from each other with the word line WL therebetween.

A direct contact DC may be electrically connected to the first impurity region SD1. In detail, the direct contact DC may be disposed on the first impurity region SD1 of the plurality of active regions ACT. That is, each of the plurality of bit lines BL may be connected to the first impurity region SD1 through the direct contact DC.

The buried contact BC may be electrically connected to the second impurity region SD2. In detail, the buried contact BC may be disposed on the second impurity region SD2 of the plurality of active regions ACT.

The semiconductor device 1 may, in some embodiments, be a dynamic random-access memory (DRAM) device.

In detail, referring to FIGS. 3A to 3D together, the semiconductor device 1 includes a plurality of active regions 118 defined by a device isolation layer 111, a substrate 110 having a plurality of word line trenches 120T crossing the plurality of active regions 118, a plurality of word lines 120 disposed inside the plurality of word line trenches 120T, a plurality of bit line structures 140, and a plurality of capacitor structures 200 including a plurality of lower electrodes 210, a capacitor dielectric layer 220, and an upper electrode 230; that is, each of the capacitor structures 200 may include a lower electrodes 210, a capacitor dielectric layer 220, and an upper electrode 230 that are sequentially stacked.

The substrate 110 may include, for example, silicon (Si), crystalline Si, polycrystalline Si, or amorphous Si. In some other embodiments, the substrate 110 may include germanium (Ge), or at least one compound semiconductor selected from silicon germanium (SiGe), silicon carbide (SiC), gallium arsenide (GaAs), indium arsenide (InAs), and indium phosphide (InP). In some embodiments, the substrate 110 may have a silicon-on-insulator (SOI) structure. For example, the substrate 110 may include a buried oxide (BOX) layer. The substrate 110 may include a conductive region, for example, a well doped with an impurity or a structure doped with an impurity.

The plurality of active regions 118 may be a portion of the substrate 110 defined by a device isolation trench 111T. The plurality of active regions 118 may have a relatively long island shape with a minor axis and a major axis when viewed in a plan view. In some embodiments, the plurality of active regions 118 may be configured having long axes arranged diagonally with respect to the first horizontal direction (X direction) and the second horizontal direction (Y direction). The plurality of active regions 118 extend in the long axis direction to have substantially the same length and may be repeatedly arranged with a generally constant pitch.

The device isolation layer 111 may fill the device isolation trench 111T. The term “fill” (or “fills,” or like terms), as may be used herein, is intended to refer broadly to either completely filling a defined space (e.g., the device isolation trench 111T) or partially filling the defined space; that is, the defined space need not be entirely filled but may, for example, be partially filled or have voids or other spaces or materials throughout. The plurality of active regions 118 may be defined on the substrate 110 by the device isolation layer 111.

In some embodiments, the device isolation layer 111 may be composed of a triple layer structure comprising a first device isolation layer, a second device isolation layer, and a third device isolation layer, but embodiments are not limited thereto. For example, the first device isolation layer may conformally cover the inner and bottom surfaces of the device isolation trench 111T. The term “cover” (or “covering,” or like terms), as may be used herein, is intended to broadly refer to an element, structure or layer that is on or over another element, structure or layer, either directly or with one or more other intervening elements, structures or layers therebetween. In some embodiments, the first device isolation layer may be made of silicon oxide. For example, the second device isolation layer may conformally cover the first device isolation layer. In some embodiments, the second device isolation layer may be made of silicon nitride. For example, the third device isolation layer may cover the second device isolation layer and fill the device isolation trench 111T. In some embodiments, the third device isolation layer may be made of silicon oxide. For example, the third device isolation layer may be made of silicon oxide formed of tonen silazene (TOSZ). In some embodiments, the device isolation layer 111 may be composed of a single layer made of one type of insulating film, a double layer made of two types of insulating films, or a multi-layer made of a combination of at least four types of insulating films. For example, the device isolation layer 111 may be composed of a single film made of silicon oxide.

The plurality of word line trenches 120T may be formed in the substrate 110 including a plurality of active regions 118 defined by the device isolation layer 111. The plurality of word line trenches 120T may extend parallel to each other in the first horizontal direction (X direction), and each of the plurality of word line trenches 120T may have a line shape that crosses the active region 118 and is arranged at substantially equal intervals in the second horizontal direction (Y direction). In some embodiments, steps may be formed on the bottom of the plurality of word line trenches 120T.

Inside the plurality of word line trenches 120T, a plurality of gate dielectric layers 122, the plurality of word lines 120, and a plurality of dummy buried insulating layers 124 may be sequentially formed. The plurality of word lines 120 may form the plurality of word lines WL illustrated in FIG. 2. The plurality of word lines 120 may extend parallel in the first horizontal direction (X direction), and each may have a line shape that crosses the active region 118 and is arranged at substantially equal intervals in the second horizontal direction (Y direction). The upper surface of each of the plurality of word lines 120 may be at a vertical level lower than the upper surface of the substrate 110. Bottom surfaces of the plurality of word lines 120 may have a convex-convex shape (facing downward), and saddle fin transistors (saddle FinFETs) may be formed in the plurality of active regions 118.

The plurality of word lines 120 may fill a lower portion of the plurality of word line trenches 120T. Each of the plurality of word lines 120 may have a stacked structure of a lower word line layer 120a and an upper word line layer 120b. For example, the lower word line layer 120a has the gate dielectric layer 122 therebetween and may conformally cover the inner wall and bottom of the lower portion of the word line trench 120T. For example, the upper word line layer 120b may cover the lower word line layer 120a, may have the gate dielectric layer 122 therebetween, and may fill a lower portion of the word line trench 120T. In some embodiments, the lower word line layer 120a may be made of a metal material such as Ti, TiN, Ta, or TaN, or a conductive metal nitride, although embodiments are not limited thereto. In some embodiments, the upper word line layer 120b may be made of, for example, doped polysilicon, a metal material such as W, a conductive metal nitride such as WN, TiSiN, or WSiN, or a combination thereof, although embodiments are not limited thereto.

A source region and a drain region formed by implanting impurity ions into a portion of the active region 118 may be disposed in a portion of the active region 118 of the substrate 110 on both (i.e., opposing) sides of each of the plurality of word lines 120.

The gate dielectric layer 122 may cover (i.e., be arranged on) the inner wall and bottom of the word line trench 120T. In some embodiments, the gate dielectric layer 122 may extend from between the word line 120 and the word line trench 120T to between the dummy buried insulating layer 124 and the word line trench 120T. The gate dielectric layer 122 may be made of at least one material selected from silicon oxide, silicon nitride, silicon oxynitride, oxide/nitride/oxide (ONO), and a high-k dielectric material having a higher dielectric constant than silicon oxide, although embodiments are not limited thereto. For example, the gate dielectric layer 122 may have a dielectric constant of about 10 to about 25. In some embodiments, the gate dielectric layer 122 is made of at least one material selected from hafnium oxide (HfO), hafnium silicate (HfSiO), hafnium oxynitride (HfON), and hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO)), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO), although embodiments are not limited thereto. For example, the gate dielectric layer 122 may be made of HfO₂, Al₂O₃, HfAlO₃, Ta₂O₃, or TiO₂.

The plurality of dummy buried insulating layers 124 may fill the upper portion of the plurality of word line trenches 120T. In some embodiments, the upper surface of the plurality of dummy buried insulating layers 124 may be at substantially the same vertical level as the upper surface of the substrate 110. The dummy buried insulating layer 124 may be made of at least one material film selected from silicon oxide, silicon nitride, silicon oxynitride, and a combination thereof, although embodiments are not limited thereto. For example, the dummy buried insulating layer 124 may be made of silicon nitride.

A first and second insulating film patterns 112 and 114 may be disposed on the device isolation layer 111, the plurality of active regions 118, and the plurality of dummy buried insulating layers 124. For example, the first and second insulating film patterns 112 and 114 may be made of silicon oxide, silicon nitride, silicon oxynitride, a metal dielectric material, or a combination thereof. In some embodiments, the first and second insulating film patterns 112 and 114 may have a stacked structure of a plurality of insulating films including a first insulating film pattern 112 and a second insulating film pattern 114. In some embodiments, the first insulating film pattern 112 may be made of silicon oxide and the second insulating film pattern 114 may be made of silicon oxynitride. In some other embodiments, the first insulating film pattern 112 may be made of a non-metallic dielectric material and the second insulating film pattern 114 may be made of a metallic dielectric material. In some embodiments, the second insulating film pattern 114 may be thicker than the first insulating film pattern 112. For example, the first insulating film pattern 112 may have a cross-sectional thickness of about 50 angstroms (Å) to about 90 Å, and the second insulating film pattern 114 is thicker than the first insulating film pattern 112 and may have a cross-sectional thickness of about 60 Å to about 100 Å.

A plurality of direct contact conductive patterns 134 may fill a portion of a plurality of direct contact holes 134H that penetrate (i.e., extend at least partially into or through) the first and second insulating film patterns 112 and 114 and expose the source region in the active region 118. The term “expose” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. In some embodiments, a direct contact hole 134H may extend within the active region 118; that is, into the source region. In some embodiments, the direct contact hole 134H may expose the first impurity region SD1. In some embodiments, the direct contact conductive pattern 134 may be electrically connected to the first impurity region SD1. In detail, the direct contact conductive pattern 134 may connect a bit line 147 to the first impurity region SD1. The direct contact conductive pattern 134 may comprise, for example, doped polysilicon. In some embodiments, the direct contact conductive pattern 134 may include an epitaxial silicon layer. The plurality of direct contact conductive patterns 134 may form the plurality of direct contacts DC illustrated in FIG. 2.

The plurality of bit line structures 140 may be disposed on the first and second insulating film patterns 112 and 114. Each of the plurality of bit line structures 140 may be composed of a bit line 147 and an insulating capping line 148 covering (i.e., on or over) the bit line 147. The plurality of bit line structures 140 may extend parallel to each other in the second horizontal direction (Y direction) parallel to a main surface of the substrate 110. The plurality of bit lines 147 may form the plurality of bit lines BL illustrated in FIG. 2. The plurality of bit lines 147 may be electrically connected to the plurality of active regions 118 through a plurality of direct contact conductive patterns 134. In some embodiments, the plurality of insulating capping lines 148 may comprise, for example, silicon nitride.

The bit line 147 may be configured to have a vertical (Z direction) stacked structure of a first metal-based conductive pattern 145 and a second metal-based conductive pattern 146 in a line shape. In some embodiments, the first metal-based conductive pattern 145 may be made of titanium nitride (TiN) or TSN (Ti—Si—N) and the second metal-based conductive pattern 146 may be made of tungsten (W), or tungsten and tungsten silicide (WSix), although embodiments are not limited thereto. In some embodiments, the first metal-based conductive pattern 145 may function as a diffusion barrier.

In some embodiments, the plurality of bit lines 147 may further include a conductive semiconductor pattern 132 disposed between the first and second insulating film patterns 112 and 114 and the first and second metal-based conductive patterns 145 and 146. The conductive semiconductor pattern 132 may be made of, for example, doped polysilicon.

In some embodiments, a plurality of insulating spacer structures 150 may cover opposing sidewalls of the plurality of bit line structures 140. The plurality of insulating spacer structures 150 may each include a first insulating spacer 152, a second insulating spacer 154, and a third insulating spacer 156. The second insulating spacer 154 may be made of a material having a lower dielectric constant than the first insulating spacer 152 and the third insulating spacer 156. In some embodiments, the first insulating spacer 152 and the third insulating spacer 156 are made of nitride, and the second insulating spacer 154 may be made of oxide. In some embodiments, the first insulating spacer 152 and the third insulating spacer 156 may be made of nitride, and the second insulating spacer 154 may be made of a material having an etch selectivity with respect to the first insulating spacer 152 and the third insulating spacer 156. For example, the first insulating spacer 152 and the third insulating spacer 156 may be made of nitride, and the second insulating spacer 154 may be an air spacer. In some embodiments, the insulating spacer structure 150 may be composed of the second insulating spacer 154 made of oxide and the third insulating spacer 156 made of nitride.

In detail, referring to FIG. 4 together, the first insulating spacer 152 may be disposed on sidewalls of the first metal-based conductive pattern 145 and sidewalls of the second metal-based conductive pattern 146. In detail, the first insulating spacer 152 may be disposed on both sidewalls of the first metal-based conductive pattern 145 and the second metal-based conductive pattern 146. For example, the first insulating spacer 152 may be selectively disposed on both sidewalls of the first metal-based conductive pattern 145 and the second metal-based conductive pattern 146.

In some embodiments, the first insulating spacer 152 may not be disposed on the sidewall of the conductive semiconductor pattern 132. In detail, the first insulating spacer 152 may not be disposed on at least a portion of the sidewall of the conductive semiconductor pattern 132. For example, at least a portion of the sidewall of the conductive semiconductor pattern 132 may not be in contact with the first insulating spacer 152.

In some embodiments, the first insulating spacer 152 may not be disposed on the sidewall of the insulating capping line 148 that covers the bit line 147. In detail, the first insulating spacer 152 may not be disposed on at least a portion of the sidewall of the insulating capping line 148 that covers the bit line 147. For example, at least a portion of the sidewall of the insulating capping line 148 may not be in contact with the first insulating spacer 152.

In some embodiments, the first insulating spacer 152 may not be disposed on the sidewall of the direct contact conductive pattern 134. In detail, the first insulating spacer 152 may not be disposed on at least a portion of the sidewall of the direct contact conductive pattern 134. For example, at least a portion of the sidewall of the direct contact conductive pattern 134 may not be in contact with the first insulating spacer 152.

In some embodiments, the second insulating spacer 154 may be disposed on the first insulating spacer 152. The second insulating spacer 154 may be disposed on both sidewalls of the bit line 147. In detail, the second insulating spacer 154 may be disposed on both sidewalls of the first metal-based conductive pattern 145 and the second metal-based conductive pattern 146 with the first insulating spacer 152 therebetween. The second insulating spacer 154 may be disposed on both sidewalls of the conductive semiconductor pattern 132, both sidewalls of the insulating capping line 148, and both sidewalls of the direct contact conductive pattern 134.

In some embodiments, the second insulating spacer 154 may be in contact with both sidewalls of the conductive semiconductor pattern 132 on both sidewalls of the conductive semiconductor pattern 132. In detail, the second insulating spacer 154 may contact at least a portion of both sidewalls of the conductive semiconductor pattern 132 on both sidewalls of the conductive semiconductor pattern 132.

In some embodiments, the second insulating spacer 154 may be in contact with both sidewalls of the insulating capping line 148 on both sidewalls of the insulating capping line 148. In detail, the second insulating spacer 154 may contact at least a portion of both sidewalls of the insulating capping line 148.

In some embodiments, the second insulating spacer 154 may contact at least a portion of both sidewalls of the direct contact conductive pattern 134. In detail, the second insulating spacer 154 may contact at least a portion of both sidewalls of the direct contact conductive pattern 134. For example, the second insulating spacer 154 may contact the upper sidewalls of the direct contact conductive pattern 134 on both sidewalls of the direct contact conductive pattern 134.

In some embodiments, the third insulating spacer 156 may be disposed on the second insulating spacer 154. The third insulating spacer 156 may be disposed on both sidewalls of the bit line 147. In detail, the third insulating spacer 156 may be disposed on both sidewalls of the first metal-based conductive pattern 145 and the second metal-based conductive pattern 146 with the first insulating spacer 152 and the second insulating spacer 154 therebetween. In detail, the third insulating spacer 156 may be disposed on both sidewalls of the conductive semiconductor pattern 132, both sidewalls of the insulating capping line 148, and both sidewalls of the direct contact conductive pattern 134 with the second insulating spacer 154 therebetween.

In some embodiments, the thickness T1 of the first insulating spacer 152 in the first horizontal direction (X direction) may be about 0.3 nm to about 1 nm. For example, the thickness T1 of the first insulating spacer 152 in the first horizontal direction (X direction) may be about 0.5 nm to about 1 nm.

In some embodiments, as described above, the first insulating spacer 152 may comprise nitride. In detail, the first insulating spacer 152 may include silicon nitride. For example, the first insulating spacer 152 may include one or more materials selected from silicon boron nitride, silicon carbon nitride, silicon oxide nitride, and silicon carbon oxynitride. For example, the first insulating spacer 152 may comprise one or more materials selected from silicon boron nitride, silicon carbon nitride, silicon oxide nitride, and silicon carbon oxynitride.

Continuing to refer to FIG. 4 together, a plurality of buried spacers 155 may be disposed on lower sidewalls of the plurality of direct contact conductive patterns 134 within the plurality of direct contact holes 134H. The plurality of buried spacers 155 may each include an insulating liner 151 and a buried insulating layer 153. The insulating spacer structure 150 may be disposed on the plurality of buried spacers 155.

In some embodiments, the insulating liner 151 may be disposed on the inner wall of the direct contact hole 134H and the lower sidewall of the direct contact conductive pattern 134. In detail, the insulating liner 151 may be disposed on the device isolation layer 111 and the lower sidewall of the direct contact conductive pattern 134 exposed by the direct contact hole 134H. For example, the insulating liner 151 may contact the lower sidewall of the direct contact conductive pattern 134 on the lower sidewall of the direct contact conductive pattern 134. The insulating liner 151 may not be disposed on the buried contact 170 recessed into the direct contact hole 134H.

In some embodiments, the buried insulating layer 153 may fill the inside of the direct contact hole 134H on the insulating liner 151. The buried insulating layer 153 may be spaced apart from the direct contact conductive pattern 134 with the insulating liner 151 therebetween. In some embodiments, the buried insulating layer 153 may contact the second insulating spacer 154 and the third insulating spacer 156 of the insulating spacer structure 150.

In some embodiments, the insulating liner 151 may include oxide and the buried insulating layer 153 may include nitride.

Referring again to FIGS. 3A to 3D, each of a plurality of insulating fences 180 may be interposed in a space between a pair of insulating spacer structures 150 facing each other between a pair of adjacent bit line structures 140. The plurality of insulating fences 180 may be spaced apart from each other in the first horizontal direction (X direction) and arranged in a row, along between a pair of adjacent insulating spacer structures 150; that is, in a second horizontal direction (Y direction). For example, the plurality of insulating fences 180 may be made of nitride.

In some embodiments, the plurality of insulating fences 180 may be formed to penetrate the first and second insulating film patterns 112 and 114 and extend into the dummy buried insulating layer 124 but are not limited thereto. In some other embodiments, the plurality of insulating fences 180 may be configured to penetrate the first and second insulating film patterns 112 and 114 but not extend into the dummy buried insulating layer 124, may be configured to extend into the first and second insulating film patterns 112 and 114 but not to penetrate the first and second insulating film patterns 112 and 114, or may not extend into the first and second insulating film patterns 112 and 114 but may be configured such that the lower surfaces of the plurality of insulating fences 180 are in contact with the first and second insulating film patterns 112 and 114.

Between each of the plurality of bit lines 147 adjacent in the first horizontal direction (X direction), a plurality of buried contact holes 170H may be defined between the plurality of insulating fences 180. The plurality of buried contact holes 170H and the plurality of insulating fences 180 may be alternately arranged between a pair of insulating spacer structures 150, that is, in the second horizontal direction (Y direction), the pair of insulating spacer structures 150 facing each other among a plurality of insulating spacer structures 150 covering both sidewalls of a plurality of bit line structures 140. The internal space of the plurality of buried contact holes 170H may be limited by the insulating spacer structure 150 covering a sidewall of each of the two bit lines 147, the buried spacer 155, the insulating fence 180, and the active region 118, wherein the insulating spacer structure 150 covers sidewalls of each of the two neighboring bit lines 147 between two neighboring bit lines 147 among the plurality of bit lines 147. In some embodiments, each of the plurality of buried contact holes 170H may extend from between the insulating spacer structure 150 and the insulating fence 180 into the active region 118. In some embodiments, each of the plurality of buried contact holes 170H may expose the second impurity region SD2.

A plurality of buried contacts 170 may be disposed within a plurality of buried contact holes 170H. The plurality of buried contacts 170 may fill a lower portion of the space between the plurality of insulating fences 180 and the plurality of insulating spacer structures 150 covering both sidewalls of each of the plurality of bit line structures 140. The plurality of buried contacts 170 and the plurality of insulating fences 180 may be alternately arranged between a pair of insulating spacer structures 150, that is, in the second horizontal direction (Y direction), the pair of insulating spacer structures 150 facing each other among a plurality of insulating spacer structures 150 covering both sidewalls of a plurality of bit line structures 140. For example, the plurality of buried contacts 170 may be made of polysilicon.

In some embodiments, the plurality of buried contacts 170 may be electrically connected to the second impurity region SD2. In detail, the plurality of buried contacts 170 may connect a corresponding plurality of landing pads 190 to the second impurity region SD2.

In some embodiments, the plurality of buried contacts 170 may be arranged in a line in each of the first horizontal direction (X direction) and the second horizontal direction (Y direction). Each of the plurality of buried contacts 170 may extend from the active region 118 in the vertical direction (Z direction) perpendicular to the substrate 110. The plurality of buried contacts 170 may form the plurality of buried contacts BC illustrated in FIG. 2.

The level of the upper surface of the plurality of buried contacts 170 may be lower than the level of the upper surface of the plurality of insulating capping lines 148 relative to the main surface of the substrate 110 being a reference base layer. The upper surfaces of the plurality of insulating fences 180 and the upper surfaces of the plurality of insulating capping lines 148 may be at the same vertical level with respect to the vertical direction (Z direction).

A plurality of landing pad holes 190H may be defined by the plurality of buried contacts 170, the plurality of insulating spacer structures 150, and the plurality of insulating fences 180. The plurality of buried contacts 170 may be exposed through the bottom of the plurality of landing pad holes 190H.

The plurality of landing pads 190 may fill at least a portion of the plurality of landing pad holes 190H and extend onto the plurality of bit line structures 140. The plurality of landing pads 190 may be separated from each other in the second horizontal direction (Y direction) by a recess portion 190R. Each of the plurality of landing pads 190 may comprise a conductive barrier film and a conductive pad material layer on the conductive barrier film. For example, the conductive barrier film may be made of metal, conductive metal nitride, or a combination thereof. In some embodiments, the conductive barrier film may have a Ti/TiN stacked structure. In some embodiments, the conductive pad material layer may include tungsten (W). In some embodiments, a metal silicide film may be formed between the landing pad 190 and the buried contact 170. The metal silicide film may be made of cobalt silicide (CoSix), nickel silicide (NiSix), or manganese silicide (MnSix) but is not limited thereto.

The plurality of landing pads 190 are disposed on the plurality of buried contacts 170, and the plurality of buried contacts 170 and the plurality of landing pads 190 corresponding to each other may be electrically connected to each other. At least a subset of the plurality of landing pads 190 may be connected to the active region 118 through a corresponding plurality of buried contacts 170. The plurality of landing pads 190 may form the plurality of landing pads LP illustrated in FIG. 2. At least a given one of the plurality of buried contacts 170 may be placed between two adjacent bit line structures 140, and at least a given one of the plurality of the landing pads 190 may extend onto one bit line structure from between two bit line structures adjacent to each other with the buried contact 170 therebetween.

The recess 190R may be filled with an insulating structure 195. In some embodiments, the insulating structure 195 may comprise an interlayer insulating layer and an etch stop layer. For example, the interlayer insulating layer may comprise an oxide and the etch stop layer may comprise a nitride. For example, the etch stop layer may include a silicon nitride layer or a silicon boron nitride (SiBN) layer. FIGS. 3A and 3C show that the upper surface of the insulating structure 195 and the upper surface of the plurality of landing pads 190 are at the same vertical level relative to the main surface of the substrate 110, but the inventive concept is not limited thereto. For example, the insulating structure 195 may fill the recess 190R and cover the upper surfaces of the plurality of landing pads 190, and may have an upper surface at a higher vertical level than the upper surfaces of the plurality of landing pads 190.

A plurality of capacitor structures 200 including a plurality of lower electrodes 210, a capacitor dielectric layer 220, and an upper electrode 230 may be disposed on the plurality of landing pads 190 and the insulating structure 195. The lower electrode 210 and the landing pad 190 that correspond to each other may be electrically connected to each other. FIGS. 3A and 3C show that the upper surface of the insulating structure 195 and the lower surface of the lower electrode 210 are at the same vertical level relative to the main surface of the substrate 110, but the inventive concept is not limited thereto.

In some embodiments, the semiconductor device 1 may further include at least one support pattern that contacts sidewalls of the plurality of lower electrodes 210 and supports the plurality of lower electrodes 210. The at least one support pattern may comprise any one of silicon nitride (SiN), silicon carbonitride (SiCN), N-rich silicon nitride (N-rich SiN), and/or Si-rich silicon nitride film (Si-rich SiN), but is not limited thereto. In some embodiments, the at least one support pattern may include a plurality of support patterns at different vertical levels so as to contact sidewalls of the plurality of lower electrodes 210 and be spaced apart from one another in the vertical direction (Z direction).

Each of the plurality of lower electrodes 210 may have a pillar shape, that is, a pillar shape with an inside filled to have a circular horizontal cross-section, but is not limited thereto. In some embodiments, each of the plurality of lower electrodes 210 may have a cylinder shape with a closed lower portion. In some embodiments, the plurality of lower electrodes 210 may be arranged in a honeycomb shape arranged in a zigzag pattern with respect to the first horizontal direction (X direction) or the second horizontal direction (Y direction). In some other embodiments, the plurality of lower electrodes 210 may be arranged in a matrix form arranged in a line in each of the first horizontal direction (X direction) and the second horizontal direction (Y direction). The plurality of lower electrodes 210 may include a metal such as tungsten or copper, a semiconductor such as silicon doped with impurities, or a conductive metal compound such as titanium nitride. In some embodiments, the plurality of lower electrodes 210 may include, for example, titanium nitride (TiN), chromium nitride (CrN), vanadium nitride (VN), molybdenum nitride (MoN), niobium nitride (NbN), titanium silicon nitride (TiSiN), titanium aluminum nitride (TiAlN), or tantalum aluminum nitride (TaAlN), although embodiments are not limited thereto.

The capacitor dielectric layer 220 may conformally cover the surfaces of the plurality of lower electrodes 210. In some embodiments, the capacitor dielectric layer 220 may be formed integrally to cover the surfaces of the plurality of lower electrodes 210 within a certain region, for example, one memory cell region (CR in FIG. 2). The term “integrally” as used herein is intended to broadly refer to an element or part that is formed as a unit with one or more other elements or parts, each of the elements or parts being essential for completeness of the unit in terms of form and/or function.

The capacitor dielectric layer 220 may include a material with antiferroelectricity characteristics, a material with ferroelectricity characteristics, or a material with a mixture of antiferroelectricity and ferroelectricity. For example, the capacitor dielectric layer 220 may be made of silicon oxide, metal oxide, or a combination thereof. In some embodiments, the capacitor dielectric layer 220 may include a dielectric material comprised of ABO₃ or MOₓ. For example, the capacitor dielectric layer 220 may be made of SiO, TaO, TaAlO, TaON, AlO, AlSIO, HO, HfSiO, ZrO, RuO, WO, HfZrO, ZrSiO, TiO, TiAlO, VO, NbO, MoO, MnO, LaO YO, CoO, NiO, CuO, ZnO, FeO, SrO, BaO, BST((Ba, Sr) TiO), STO(SrTiO), BTO(BaTiO), PTO(PbTiO), AgNbO, BiFeO, PZT (Pb(Zr,Ti)O), (Pb,La)(Zr,Ti)O, Ba(Zr,Ti)O, Sr(Zr,Ti)O, or a combination thereof.

The upper electrode 230 may be formed integrally with a plurality of lower electrodes 210 within a certain region, for example, one memory cell region (CR in FIG. 2). A plurality of lower electrodes 210, a capacitor dielectric layer 220, and an upper electrode 230 may form a plurality of capacitor structures 200 within a certain region, for example, one memory cell region (CR in FIG. 2).

The upper electrode 230 may include a metal such as tungsten or copper, a semiconductor such as silicon doped with impurities, or a conductive metal compound such as titanium nitride, although embodiments are not limited thereto. In some embodiments, the upper electrode 230 may include TiN, CrN, VN, MoN, NbN, TiSiN, TiAlN, or TaAlN. In some embodiments, the upper electrode 230 may have a stacked structure of at least two of a semiconductor material layer doped with impurities, a main electrode layer, and an interface layer. The doped semiconductor material layer may include, for example, doped polysilicon or doped polycrystalline silicon germanium (SiGe). The main electrode layer may be made of a metal material. The main electrode layer may be made of, for example, W, Ru, RuO, Pt, PtO, Ir, IrO, SRO(SrRuO), BSRO((Ba,Sr)RuO), CRO (CaRuO), BaRuO, La(Sr,Co)O, etc. In some embodiments, the main electrode layer may be made of W. The interface layer may include at least one of metal oxide, metal nitride, metal carbide, and metal silicide.

According to embodiments, a semiconductor device 1 including a first insulating spacer 152 covering both sidewalls of the first metal-based conductive pattern 145 and the second metal-based conductive pattern 146 may be provided. The first insulating spacer 152 may prevent oxidation and/or elution of the first metal-based conductive pattern 145 and the second metal-based conductive pattern 146, which may occur in subsequent processes. That is, according to one or more embodiments of the present disclosure, a semiconductor device 1 with improved performance and reliability may be provided.

According to embodiments, the semiconductor device 1 may be provided in which the first insulating spacer 152 is not disposed on the sidewall of the direct contact conductive pattern 134. Thereby, defects may be improved by increasing the width of the buried insulating layer 153 of the buried spacer 155 disposed in the direct contact hole 134H in the first horizontal direction (X direction). That is, according to embodiments, a semiconductor device 1 with improved performance and reliability may be provided.

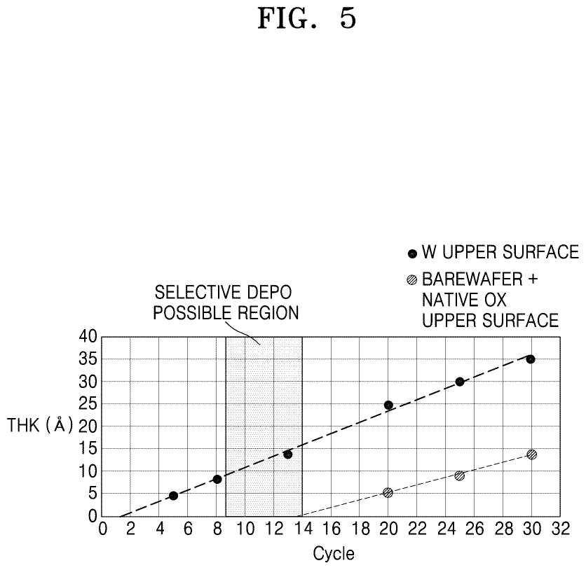

FIG. 5 is a graph for explaining a method of manufacturing a semiconductor device according to embodiments. In detail, FIG. 5 is a graph showing the results of an experiment in which silicon nitride was applied to two different surfaces using a dichlorosilane (DCS) precursor and an atomic layer deposition (ALD) process. In other words, FIG. 5 is a graph showing the experimental results of applying silicon nitride on a metal (for example, tungsten (W)) using a DCS precursor and the experimental results of applying silicon nitride on an oxide. In particular, when silicon nitride is applied on the oxide, silicon nitride is applied thereto without removing the natural oxide formed on the bare wafer. The horizontal axis of the graph represents the number of cycles of ALD, and the vertical axis of the graph represents the thickness (A) of the applied silicon nitride layer.

In some embodiments, the DCS precursor may be used to form the first insulating spacer 152 (see FIG. 4). DCS precursors have an incubation time when used under certain conditions. In other words, when attempting to apply a specific material through an ALD process using the DCS precursor, the cycle at which deposition begins on different surfaces is different. For example, when using the DCS precursor to apply a layer of material A, the layer of material A may begin to be applied from the second cycle on a first surface made of material B, while the layer of material A may begin to be applied from the 14th cycle on a second surface made of material C.

Referring to FIG. 5, when the ALD process was performed to apply silicon nitride in an environment of 630° C. using the DCS precursor, deposition of silicon nitride proceeds almost immediately on tungsten (W), and a silicon nitride layer with a thickness of approximately 5 Å is observed in the fifth cycle. On the other hand, it may be seen that a silicon nitride layer with a thickness of about 1 Å was observed on the native oxide on the bare wafer after the 14th cycle. In particular, in the 14th cycle, where a silicon nitride layer was formed on the native oxide on the bare wafer, it may be seen that a silicon nitride layer with a thickness of about 15 Å was formed on the tungsten (W).

That is, when performing the ALD process to apply silicon nitride using the DCS precursor, when the ALD process is stopped after only about the 14th cycle, a silicon nitride layer may be applied to a thickness of about 15 Å only on the tungsten (W), and the silicon nitride layer may not be applied on the oxide. Alternatively, the ALD process may be stopped when the desired thickness is achieved, even before about the 14th cycle, to obtain a silicon nitride layer of a desired thickness of about 15 Å or less.

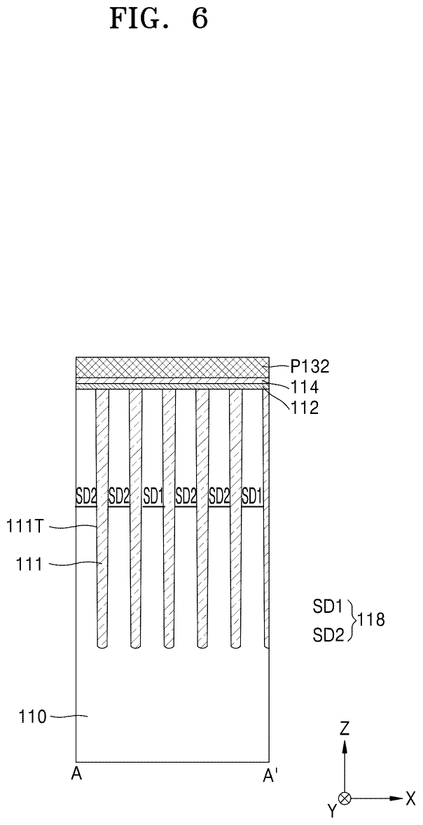

FIGS. 6 to 14 are schematic diagrams showing intermediate processes in an example method of manufacturing a semiconductor device, according to one or more embodiments. In detail, FIGS. 6 to 14 are cross-sectional views depicting at least a portion of the illustrative semiconductor device 1 of FIG. 1, taken along line A-A′ in FIG. 1.

Referring to FIG. 6, a plurality of device isolation trenches 111T and a plurality of device isolation layers 111 may be formed on a substrate 110 to define a plurality of active regions 118. Subsequently, although not explicitly shown, the plurality of word lines 120 (see FIGS. 3B to 3D) extending in the first horizontal direction (X direction) may be formed on the substrate 110.

Subsequently, insulating film patterns 112 and 114 may be formed on the substrate 110, and a pre-conductive semiconductor pattern P132 may be formed on the first and second insulating film patterns 112 and 114. For example, the pre-conductive semiconductor pattern P132 may include polysilicon.

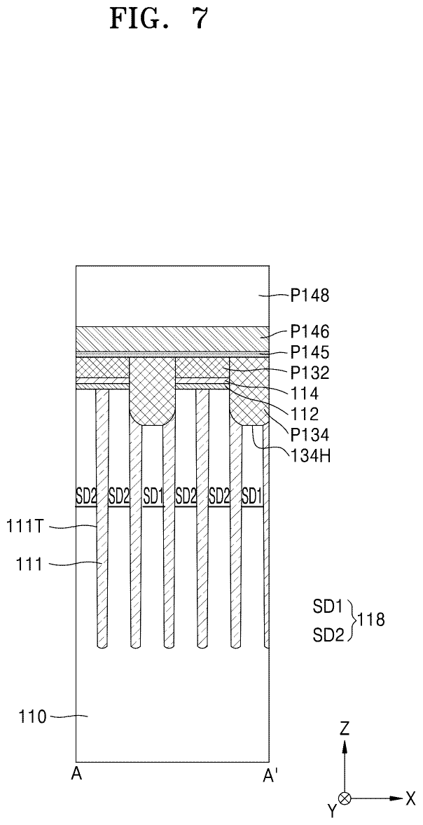

Referring to FIG. 7, after forming a first mask pattern (not explicitly shown) on the pre-conductive semiconductor pattern P132 (e.g., using standard photolithography), a direct contact hole 134H exposing the first impurity region SD1 of the substrate 110 may be formed, such as by etching the pre-conductive semiconductor pattern P132 and the first and second insulating film patterns 112 and 114 exposed through the opening (not shown) of the first mask pattern and etching the portion of the substrate 110 and the device isolation layer 111 exposed as a result of the etching.

Thereafter, the first mask pattern is removed, and a pre-direct contact P134 is formed in the direct contact hole 134H. In an example process of forming a pre-direct contact P134, a conductive layer of sufficient thickness to fill the direct contact hole 134H may be formed inside the direct contact hole 134H and on the upper portion of the pre-conductive semiconductor pattern P132, and an etch-back process may be performed on the conductive layer so that the conductive layer remains only within the direct contact hole 134H. The conductive layer may include polysilicon.

Thereafter, a pre-first metal-based conductive pattern P145, a pre-second metal-based conductive pattern P146, and a pre-insulating capping line P148 may be sequentially formed on the pre-conductive semiconductor pattern P132 and the pre-direct contact P134.

The pre-first metal-based conductive pattern P145 and the pre-second metal-based conductive pattern P146 may each include TiN, TiSiN, W, tungsten silicide, or a combination thereof, although embodiments are not limited thereto.

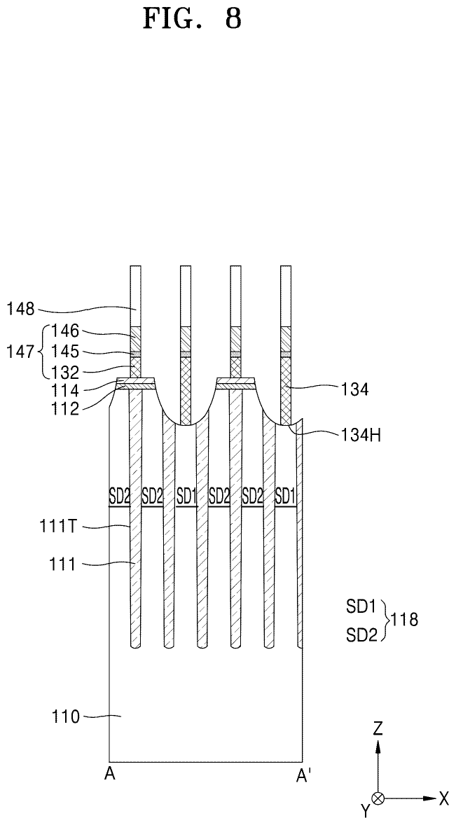

Referring to FIG. 8, the pre-insulating capping line P148, the pre-second metal-based conductive pattern P146, the pre-first metal-based conductive pattern P145, the pre-conductive semiconductor pattern P132, and the pre-direct contact P134 may be patterned. As a result, a direct contact conductive pattern 134 disposed in the direct contact hole 134H, an insulating capping line 148, and a bit line 147 including a conductive semiconductor pattern 132, a first metal-based conductive pattern 145, and a second metal-based conductive pattern 146 may be formed.

To form the direct contact hole 134H, a portion of the substrate 110, a portion of the device isolation layer 111, and a portion of the first and second insulating film patterns 112 and 114 may be etched. By the direct contact hole 134H, not only the first impurity region SD1 to which the direct contact conductive pattern 134 is connected but also the second impurity region SD2 may be exposed. In detail, two second impurity regions SD2 spaced apart in the first horizontal direction (X direction) with the first impurity region SD1 therebetween may also be at least partially exposed by the direct contact hole 134H.

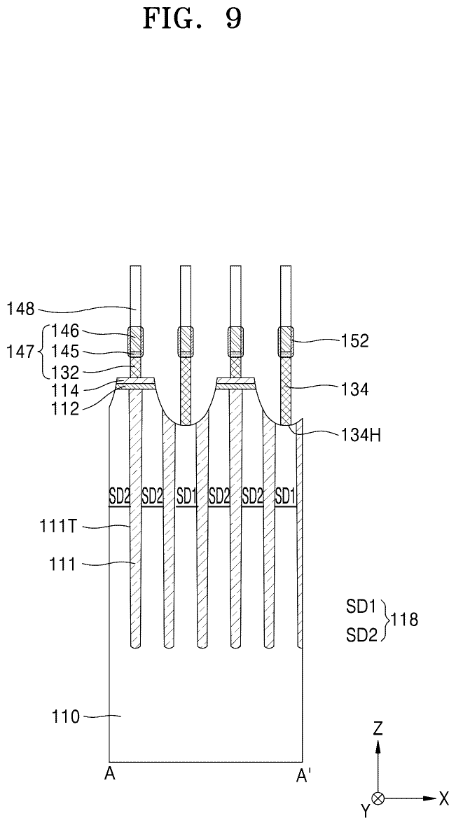

Referring to FIG. 9, a first insulating spacer 152 may be formed on the sidewalls of the first metal-based conductive pattern 145 and the sidewalls of the second metal-based conductive pattern 146. The first insulating spacer 152 may include silicon nitride. To form the first insulating spacer 152, an ALD process may be performed in an environment of about 630° C. using a DCS precursor.

In detail, one cycle of applying a silicon nitride layer in which the DCS precursor is applied and ammonia (NH₃) is applied may proceed. In this case, until a certain cycle, a silicon nitride layer may be applied only on the sidewalls of the first metal-based conductive pattern 145 and the second metal-based conductive pattern 146, and the silicon nitride layer may not be applied on non-metallic surfaces, such as conductive semiconductor patterns 132, insulating capping lines 148, and active regions 118 and device isolation layers 111 exposed by the direct contact hole 134H. For example, until the 8th cycle progresses, the silicon nitride layer may be applied only on the sidewalls of the first metal-based conductive pattern 145 and the second metal-based conductive pattern 146. By stopping the injection of the DCS precursor and NH₃ once a silicon nitride layer of the desired thickness is applied on the sidewalls of the first metal-based conductive pattern 145 and the second metal-based conductive pattern 146, the ALD cycle may be prevented from proceeding further. For example, when the silicon nitride layer with a thickness of about 10 Å is applied on the sidewalls of the first metal-based conductive pattern 145 and the second metal-based conductive pattern 146, the ALD cycle may be stopped. In particular, the ALD cycle may be stopped once a silicon nitride layer of the desired thickness is applied to the sidewalls of the first and second metal-based conductive patterns 145 and 146 and before silicon nitride is applied to undesired surfaces, such as conductive semiconductor patterns 132, insulating capping lines 148, active regions 118, and device isolation layers 111.

The first insulating spacer 152 may be formed through the above process. The thickness of the first insulating spacer 152 in the first horizontal direction (X direction) may be about 10 Å or more. That is, the initial thickness of the first insulating spacer 152 in the first horizontal direction (X direction) may be about 10 Å or more.

According to one or more embodiments, as a first insulating spacer 152 having an initial thickness of about 10 Å or more is formed, oxidation and/or elution of the first metal-based conductive pattern 145 and the second metal-based conductive pattern 146 may be prevented in the subsequent etching process.

In some other embodiments, in addition to the DCS precursor, a silicon tetrachloride (TCS) precursor or a diiodosilane (DIS) precursor may be used.

In some other embodiments, along with NH₃, a gas including another substance, for example, one selected from boron (B), carbon (C), and oxygen (O), may be applied. Accordingly, the first insulating spacer 152 may be formed including silicon boron nitride, silicon carbon nitride, silicon oxide nitride, or silicon carbon oxynitride.

In some other embodiments, selectivity may be improved by using more inhibitors. For example, the selectivity may be improved by using more HCl.

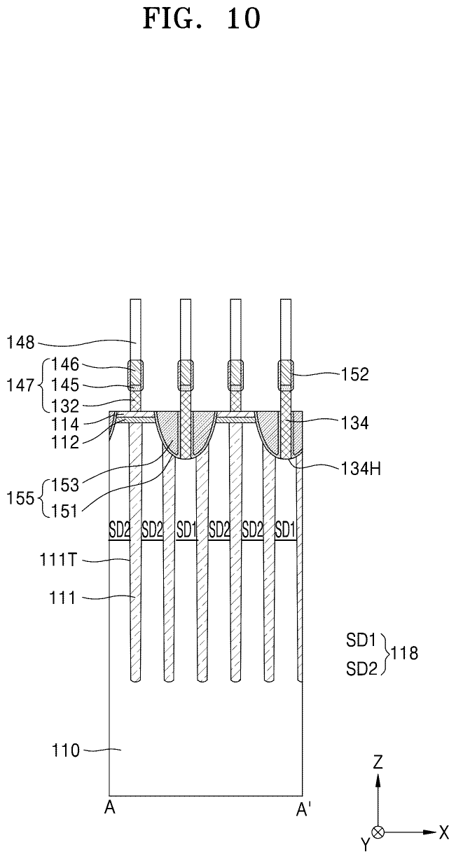

Referring to FIG. 10, a plurality of buried spacers 155 may be formed in the direct contact hole 134H. In detail, the buried spacers 155 may be formed on the lower portions of both (opposing) sidewalls of the plurality of direct contact conductive patterns 134 within the direct contact hole 134H.

In detail, an insulating liner 151 may be formed on the inner wall of the direct contact hole 134H and the lower sidewall of the direct contact conductive pattern 134. For example, an insulating liner 151 may be formed on the side surfaces of the first and second insulating film patterns 112 and 114, the second impurity region SD2, the device isolation layer 111, and the first impurity region SD1 exposed by the direct contact hole 134H. For example, an insulating liner 151 may be formed on the lower portions of both sidewalls of the direct contact conductive pattern 134 within the direct contact hole 134H. The insulating liner 151 may include an oxide.

Subsequently, a buried insulating layer 153 may be formed on the insulating liner 151. The buried insulating layer 153 may fill the inside of the direct contact hole 134H on the insulating liner 151.

The process of forming the buried spacer 155 may include burying an insulating material inside the direct contact hole 134H and between the plurality of bit line structures 140, and etching the upper insulating material. In detail, a process of removing the insulating material so that the upper surface of the buried spacer 155 is at the same vertical level as (i.e., coplanar with) the upper surface of the first and second insulating film patterns 112 and 114 may be included. By the etching process, the width of the first insulating spacer 152 in the first horizontal direction (X direction) may be reduced. For example, the width of the first insulating spacer 152 in the first horizontal direction (X direction) may be reduced from about 3 Å or more to about 10 Å or less.

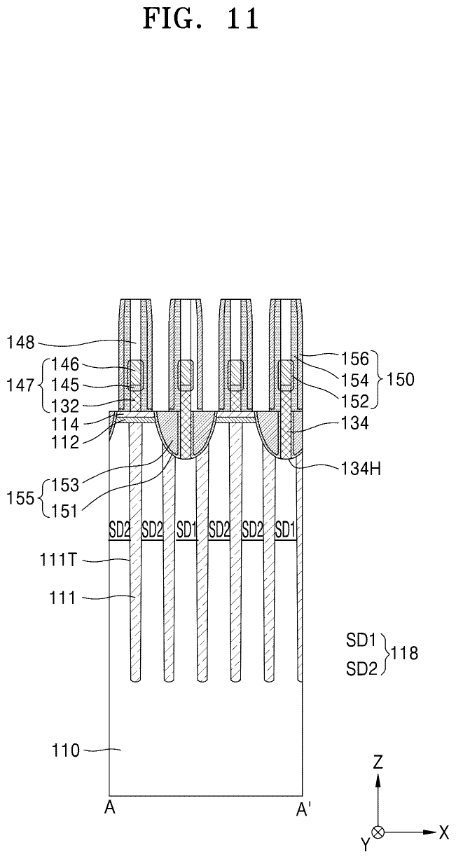

Referring to FIG. 11, an insulating spacer structure 150 may be formed on both (opposing) sidewalls of the bit line structure 140.

In detail, a second insulating spacer 154 may be formed on the first insulating spacer 152. The second insulating spacer 154 may be disposed on both sidewalls of the first metal-based conductive pattern 145 and the second metal-based conductive pattern 146 with the first insulating spacer 152 therebetween. The second insulating spacer 154 may be disposed on at least a portion of both sidewalls of the conductive semiconductor pattern 132, at least a portion of both sidewalls of the insulating capping line 148, and at least a portion of both sidewalls of the direct contact conductive pattern 134. The second insulating spacer 154 may be disposed on a portion of the upper surface of the buried spacer 155.

Subsequently, the third insulating spacer 156 may be formed on the second insulating spacer 154. The third insulating spacer 156 may be disposed on a portion of the upper surface of the buried spacer 155.

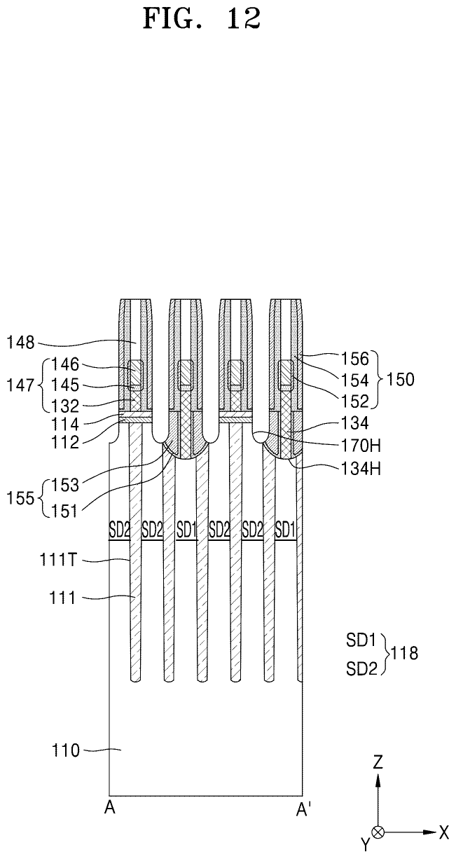

Referring to FIG. 12, a portion of the substrate 110 and the device isolation layer 111 may be etched to form a plurality of buried contact holes 170H.

In detail, a buried layer (not shown) that fills the space between the plurality of insulating spacer structures 150 may be formed on the buried spacer 155. Thereafter, a plurality of buried contact holes 170H may be formed by etching a portion of the buried layer, the first and second insulating film patterns 112 and 114, the buried spacer 155, the substrate 110, and the device isolation layer 111.

Through the above process, a plurality of buried contact holes 170H exposing the second impurity region SD2 may be formed.

In this case, in the previous process according to embodiments, the first insulating spacer 152 may not be disposed on the active region 118 and the device isolation layer 111. Thereby, when misalignment occurs during the etching process to form the plurality of buried contact holes 170H, the defect in which the second impurity region SD2 is not exposed due to the insulating material may be improved.

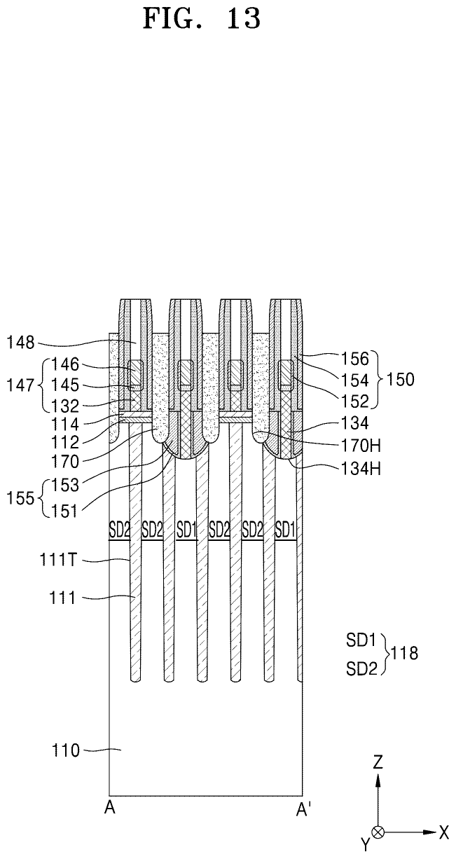

Referring to FIG. 13, a plurality of buried contacts 170 may be formed by filling the plurality of buried contact holes 170H with a conductive material. The process of forming the buried contact 170 may include filling the plurality of buried contact holes 170H with a conductive material and then etching an upper portion of the conductive material.

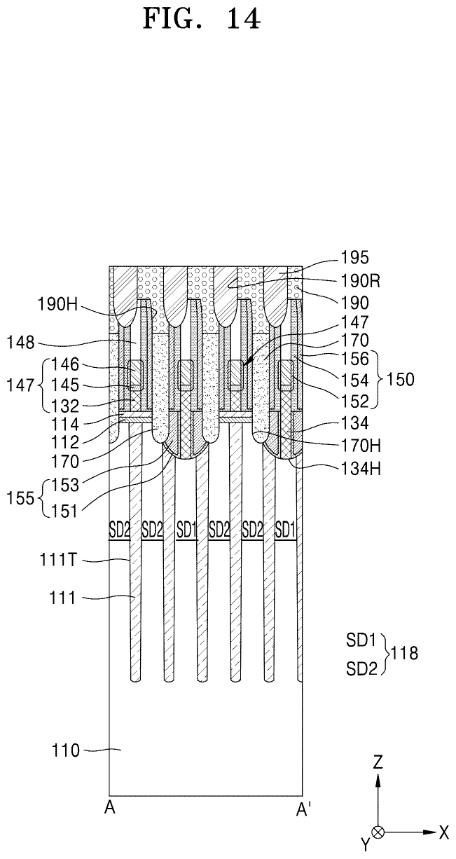

Referring to FIG. 14, a landing pad 190 and an insulating structure 195 may be formed on the plurality of buried contacts 170.

Subsequently, a process may be performed to manufacture the semiconductor device 1 described with reference to FIGS. 1, 2, 3A to 3D, and 4.

While the inventive concept has been particularly shown and described with reference to embodiments thereof, it will be understood that various changes in form and details may be made therein without departing from the spirit and scope of the following claims.

What is claimed is:

1. A semiconductor device, comprising:
a substrate;
an active region defined by a device isolation layer within the substrate;
a word line extending in a first horizontal direction within the substrate, the first horizontal direction parallel to an upper surface of the substrate;
a bit line extending on the substrate in a second horizontal direction parallel to the upper surface of the substrate and intersecting with the first horizontal direction, the bit line including a metal-based conductive pattern;
a first spacer on a sidewall of the metal-based conductive pattern;
a second spacer on the first spacer;
a direct contact in a direct contact hole exposing the active region, the direct contact electrically connecting the bit line to the active region; and
a buried spacer on a lower portion of a sidewall of the direct contact within the direct contact hole,
wherein the second spacer contacts the sidewall of the direct contact.

2. The semiconductor device of claim 1,
wherein the bit line further includes a conductive semiconductor pattern between the metal-based conductive pattern and the substrate, and
a sidewall of the conductive semiconductor pattern includes at least a portion that is not in contact with the first spacer.

3. The semiconductor device of claim 2, wherein the second spacer is in contact with the sidewall of the conductive semiconductor pattern.

4. The semiconductor device of claim 1, wherein the sidewall of the direct contact includes at least a portion that is not in contact with the first spacer.

5. The semiconductor device of claim 1, wherein the first spacer includes a nitride, and the second spacer includes an oxide.

6. The semiconductor device of claim 5, wherein the first spacer includes one or more materials selected from silicon boron nitride, silicon carbon nitride, silicon oxide nitride, and silicon carbon oxynitride.

7. The semiconductor device of claim 1,
wherein the buried spacer comprises:
an insulating liner on an inner wall of the direct contact hole and the lower portion of the sidewall of the direct contact; and
a buried insulating layer at least partially filling the direct contact hole on the insulating liner.

8. The semiconductor device of claim 7, wherein the insulating liner is in contact with the lower portion of the sidewall of the direct contact.

9. The semiconductor device of claim 7, wherein the insulating liner includes an oxide, and the buried insulating layer includes a nitride.

10. The semiconductor device of claim 1, wherein a thickness of the first spacer in the first horizontal direction is about 0.3 nm to about 1 nm.

11. A semiconductor device, comprising:
a substrate;
an active region defined by a device isolation layer within the substrate;
a word line crossing the active region in a first horizontal direction parallel to an upper surface of the substrate, the word line dividing the active region into a first impurity region and a second impurity region;
a bit line extending in a second horizontal direction parallel to the upper surface of the substrate and intersecting with the first horizontal direction on the substrate, the bit line including a conductive semiconductor pattern and a metal-based conductive pattern that are sequentially stacked;
a first spacer on a sidewall of the metal-based conductive pattern;
a second spacer on the first spacer;
a direct contact in a direct contact hole at least partially exposing the first impurity region, the direct contact electrically connecting the bit line to the first impurity region;
a buried contact in a buried contact hole at least partially exposing the second impurity region, wherein the buried contact is electrically connected to the second impurity region on a sidewall of the bit line; and
a buried spacer on a lower portion of a sidewall of the direct contact within the direct contact hole,
wherein the second spacer contacts a sidewall of the conductive semiconductor pattern.

12. The semiconductor device of claim 11, wherein the second spacer is in contact with an upper portion of the sidewall of the direct contact.

13. The semiconductor device of claim 12, wherein the sidewall of the direct contact includes at least a portion that is not in contact with the first spacer.

14. The semiconductor device of claim 11, wherein the sidewall of the conductive semiconductor pattern includes at least a portion that is not in contact with the first spacer.

15. The semiconductor device of claim 11, wherein the first spacer includes a nitride, and the second spacer includes an oxide.

16. The semiconductor device of claim 11,
wherein the buried spacer comprises:
an insulating liner on an inner wall of the direct contact hole and the lower sidewall of the direct contact, and in contact with the lower sidewall of the direct contact; and
a buried insulating layer at least partially filling the direct contact hole on the insulating liner.

17. The semiconductor device of claim 16, wherein the insulating liner includes an oxide, and the buried insulating layer includes a nitride.

18. A semiconductor device, comprising:
a substrate;
a device isolation layer defining an active region within the substrate, the active region including a first impurity region and second impurity regions, the second impurity regions spaced apart from each other with the first impurity region therebetween;
a word line crossing between the first impurity region and the second impurity regions and extending in a first horizontal direction within the substrate, the first horizontal direction parallel to an upper surface of the substrate;
a bit line extending on the substrate in a second horizontal direction, the second horizontal direction parallel to the upper surface of the substrate and intersecting with the first horizontal direction, the bit line including a conductive semiconductor pattern and a metal-based conductive pattern that are sequentially stacked;
a first spacer on a sidewall of the metal-based conductive pattern and including a nitride;
a second spacer on the first spacer and a sidewall of the conductive semiconductor pattern and including an oxide;
a direct contact in a direct contact hole exposing the first impurity region, the direct contact electrically connecting the bit line to the first impurity region;
a buried contact in a buried contact hole exposing the second impurity region, wherein the buried contact is electrically connected to the second impurity region on a sidewall of the bit line; and
a buried spacer on a lower sidewall of the direct contact within the direct contact hole,
wherein the second spacer contacts a sidewall of the direct contact on the sidewall of the direct contact, and contacts the sidewall of the conductive semiconductor pattern on the sidewall of the conductive semiconductor pattern.

19. The semiconductor device of claim 18,
wherein the sidewall of the conductive semiconductor pattern includes at least a portion that is not in contact with the first spacer, and
the sidewall of the direct contact includes at least a portion that is not in contact with the first spacer.

20. The semiconductor device of claim 18,
wherein the buried spacer comprises:
an insulating liner on an inner wall of the direct contact hole and the lower sidewall of the direct contact, in contact with the lower sidewall of the direct contact, and comprising an oxide; and
a buried insulating layer that at least partially fills the direct contact hole on the insulating liner and includes a nitride.
